(19) United States
(12) Patent Application Publication
(10) Pub. No.: US 2011/0006835 A1
(43) Pub. Date: Jan. 13, 2011

(54) MULTI-CHIP SYSTEM

(76) Inventors: Byoungsul Kim, Suwon-si (KR); Kwangwon Park, Suwon-si (KR); Hakyong Lee, Suwon-si (KR); Joo-Youn Lim, Seoul (KR)

Correspondence Address: F. CHAU & ASSOCIATES, LLC, 130 WOODBURY ROAD, WOODBURY, NY, 11797, US

(21) Appl. No.: 12/797,813

(22) Filed: Jun. 10, 2010

(30) Foreign Application Priority Data
Jul. 8, 2009 (KR) 10-2009-0062190

(51) Int. Cl. G11C 5/14

(52) U.S. Cl. 327/530

(57) ABSTRACT

Provided is a multi-chip system. The multi-chip system includes a plurality of chips and a power sequence controller. The power sequence controller supplies a plurality of external power voltages to the plurality of chips according to a predetermined sequence.

### CROSS-REFERENCE TO RELATED APPLICATIONS

This U.S. non-provisional patent application claims priority under 35 U.S.C. §119 of Korean Patent Application No. 10-2009-0062190, filed on Jul. 8, 2009, the entire contents of which are hereby incorporated by reference.

### BACKGROUND

The present disclosure herein relates to a multi-chip system.

With the development of digital signal processing technologies, the signal processing of logic elements used in audio, video, and communication systems is being rapidly converted from analog signal processing to digital signal processing. Multi-chip packages are therefore being developed to facilitate this conversion. In multi-chip packages, a logic chip (such as a micro device) and a memory chip (capable of storing/restoring information) are sequentially stacked and the logic chip and the memory chip are then electrically connected. The memory chip and the logic chip are therefore packaged together rather than individually packaged. Accordingly, a multi-chip package occupies a smaller space than multiple conventional packages, thereby enabling miniaturization of electronic products.

### SUMMARY

The present disclosure provides a multi-chip system that does not cause defects during the power supply sequence.

The present disclosure also provides a multi-chip system that inhibits a loss of chip function due to generation of the maximum current.

Embodiments of these and other inventive concepts provide multi-chip systems comprising a plurality of chips and a power sequence controller configured to supply a plurality of external power voltages to the plurality of chips according to a predetermined sequence.

In some embodiments, the plurality of chips may have a stacked structure.

In other embodiments, the plurality of chips may be memory chips of the same type.

In still other embodiments, the power sequence controller may delay supplying at least one of the external power voltages according to the predetermined sequence.

In other embodiments, at least two of the plurality of the power voltages may have different levels.

In yet other embodiments, multi-chip systems can include a first chip capable of generating an enabling signal when a first power voltage is supplied and reaches a certain level and a second chip that can be supplied with a second power voltage in response to the enabling signal.

In some embodiments, the first chip may be a slave, and the second chip may be a master.

In still other embodiments, a multi-chip system can include at least one first chip that is supplied with a first power voltage; at least one second chip that is configured to be supplied with a second power voltage; and a power sequence controller that is configured to receive the first and second power voltages and supply the second power voltage to the at least one second chip after supplying the first power voltage to the at least one first chip.

### BRIEF DESCRIPTION OF THE DRAWINGS

The accompanying drawings are included to provide further understanding of the inventive concept, and are incorporated in and constitute a part of this specification. The drawings illustrate exemplary embodiments of the inventive concepts and, together with the description, serve to explain various principles and aspects of the inventive concepts. In the drawings:

FIG. 1 is a schematic block diagram illustrating a multi-chip system according to a first embodiment;

FIGS. 2A and 2B are schematic block diagrams illustrating a power supply sequence when a multi-chip system is powered up;

FIG. 3 is a schematic block diagram illustrating a power sequence controller configured for use in the multi-chip system embodiment shown in FIG. 1;

FIG. 4 is a schematic illustration of a multi-chip package for use in the multi-chip system of FIG. 1;

FIG. 5 is a schematic block diagram illustrating a moviNAND according to another aspect of these inventive concepts;

FIG. 6 is a schematic block diagram illustrating an exemplary power sequence controller for the moviNAND shown in FIG. 5;

FIG. 7 is a schematic diagram illustrating a power supply sequence in the power sequence controller of FIG. 6;

FIG. 8 is a schematic block diagram illustrating a multi-chip system according to another embodiment;

FIG. 9 is a schematic illustration of a multi-chip package configured having the multi-chip system of FIG. 8;

FIG. 10 is a flowchart illustrating a power-up method for multi-chip systems according to various embodiments of these inventive concepts;

FIG. 11 is a schematic block diagram illustrating a host system according to another aspect of these inventive concepts; and

FIG. 12 is a schematic block diagram illustrating a Solid State Drive (SSD) according to a still further aspect of these inventive concepts.

### DETAILED DESCRIPTION OF THE EMBODIMENTS

Exemplary aspects and embodiments of the inventive concepts will now be described below in more detail with reference to the accompanying drawings. It should be noted, however, that the inventive concepts may be embodied in different forms and should not be construed as being limited to the specific aspects and embodiments set forth herein. Rather, these aspects and embodiments are included to provide a thorough and complete disclosure and to fully convey the scope of the inventive concept to those skilled in the art.

A multi-chip system according to one embodiment of the inventive concept may be configured to supply power voltages to respective chips according to a predetermined sequence. Thus, the multi-chip system can be inhibited from being simultaneously supplied with all power voltages, and can thereby perform a stable power-up operation.

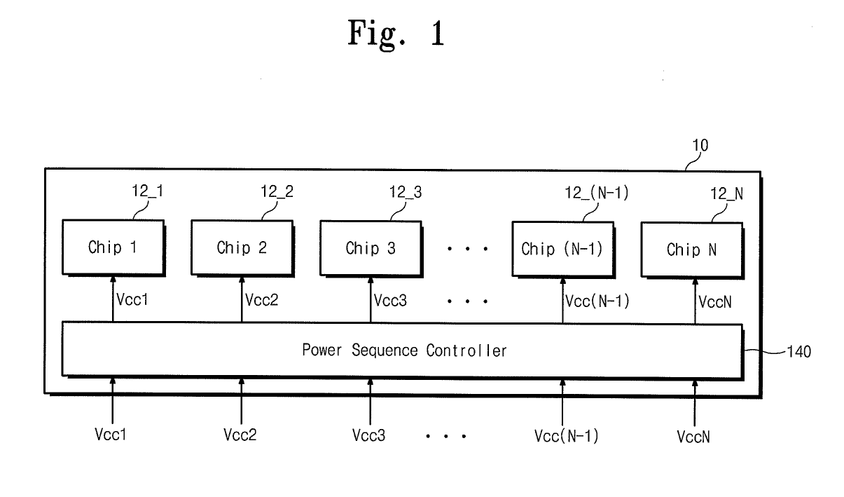

FIG. 1 is a schematic block diagram illustrating a multi-chip system according to one embodiment. Referring to FIG. 1, a multi-chip system 10 may include a plurality of chips 12_1, 12_2, . . . , 12_N and a power sequence controller 140.

The plurality of chips 12_1, 12_2, . . . , 12_N may include at least two chips of different types. In this case, the plurality of chips 12_1, 12_2, . . . , 12_N may be connected to one another with a relationship of master and slave. Here, the master may serve as a subject for performing certain operations, and the slave may serve as a subordinate that behaves according to the instructions of the master.

The plurality of chips 12_1, 12_2, . . . , 12_N may include chips of the same type. For example, the plurality of chips 12_1, 12_2, . . . , 12_N may be NAND flash memories of the same type.

Power voltages Vcc1, Vcc2, . . . , VccN may be supplied to the plurality of chips 12_1, 12_2, . . . , 12_N. The power voltages Vcc1, Vcc2, . . . , VccN need not be directly supplied from the outside to the plurality of chips 12_1, 12_2, . . . , 12_N, but may be supplied to the plurality of chips 12_1, 12_2, . . . , 12_N through the power sequence controller 40.

The power sequence controller 40 may supply respective ones of the external power voltages Vcc1, Vcc2, . . . , VccN to respective ones of the plurality of chips 12_1, 12_2, . . . , 12_N according to a predetermined sequence. That is, the power sequence controller 40 may control the supply of the inputted power voltages Vcc1, Vcc2, . . . , VccN according to a predetermined sequence. Here, the sequence may be determined in advance by a manufacturer of the multi-chip system 10.

As another example, the sequence may be determined in advance according to the state of the inputted power voltage of the multi-chip system 10.

Accordingly, in the multi-chip system 10 constructed according to this embodiment of the inventive concepts, the power voltages may be supplied to the respective chips according to a predetermined sequence. Thus, the multi-chip system 10 may inhibit all power voltages from being simultaneously supplied. Accordingly, the amount of peak current can be reduced in the multi-chip system 10, resulting in a reduction in the number of malfunctions of the multi-chip system 10 caused by the peak current.

It should be noted that although FIG. 1 illustrates that N number of power voltages are supplied to N number of chips,

a multi-chip system of an embodiment of the inventive concept is not necessarily limited to such an embodiment. The multi-chip system may be configured such that a smaller number of power voltages than N are supplied to N number of chips. For example, the same power voltage may be supplied to multiple chips. In addition, any of the one or more power voltages can be applied to any of the various chips in any desired order or sequence. For example, a first voltage could be supplied to a first chip before a second voltage is supplied to a second chip, and so on until the Nth voltage is applied to the Nth chip. Alternatively, the Nth voltage could be applied to the Nth chip before the (N-1)th voltage is applied to the (N-1)th chip, and so forth, until the first voltage is applied to the first chip. The power sequence controller could further be used to supply power voltages to any of the other chips before the first or Nth chips, in any desired order or sequence.

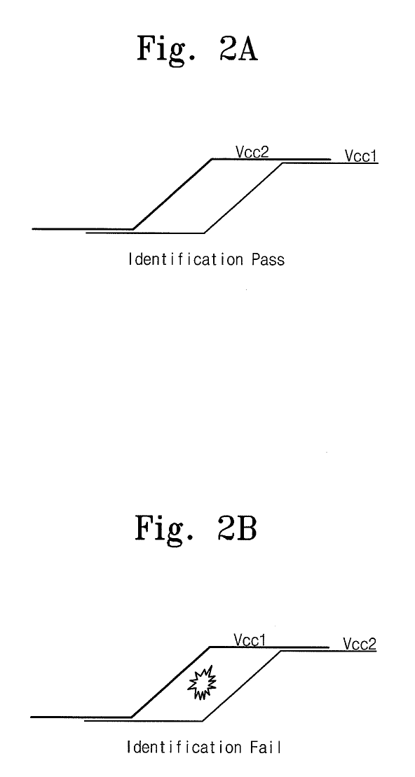

Also, by supplying power voltages according to a predetermined sequence, the multi-chip system 10 can prevent a system failure (such as a failure of a chip recognition operation) that may be generated upon power-up. The failure of the chip recognition operation will be described in detail with reference to FIG. 2.

FIG. 2 is a schematic diagram illustrating the need for the power supply sequence when a multi-chip system is powered up. Referring to FIG. 2, a first chip Chip1 is a master, and a second chip Chip2 is a slave. Alternatively, the first chip Chip1 can be a slave and the second chip Chip2 can be a master. Also, a voltage enabling the first chip Chip1 is a first power voltage Vcc1, and a voltage enabling the second chip Chip2 is a second power voltage Vcc2. In other words, the first power voltage Vcc1 is a power voltage for the master, and the second power voltage Vcc2 is a power voltage for the slave.

The first chip Chip1 may first perform an operation for recognizing the second chip Chip2 when a multi-chip system is powered up. For this, the first chip Chip1 may transmit a command to the second chip Chip2 for recognizing what the second chip Chip2 is.

If, as shown in FIG. 2A, the first chip Chip1 is enabled after the second chip Chip2 is first enabled, the recognition operation may be performed normally. That is, the enabled second chip Chip2 may transmit an identification number (e.g., Carrier Identification Parameter (CIP)) in response to an identification command transmitted from the first chip Chip1. Thus, the identification operation for the second chip Chip2 may be completed.

On the other hand, if, as illustrated in FIG. 2B, the first chip Chip1 is enabled, but the second chip Chip2 is not yet enabled, then the identification operation may fail. That is, since the second chip Chip2 is not enabled, the second chip Chip2 cannot respond to the identification command of the first chip Chip1. Therefore, the identification operation for the second chip Chip2 will fail.

Accordingly, the power supply sequence may be configured such that the first chip Chip1 is enabled after the second chip Chip2 is enabled. Accordingly, when the power voltages are supplied in such a sequence, the failure of the chip identification operation can be prevented.

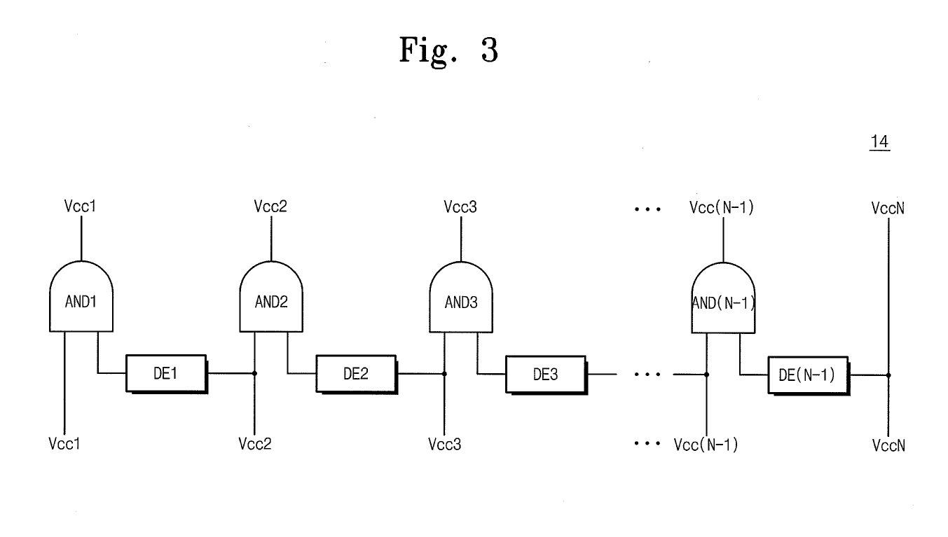

The power sequence controller 140 may be configured having a structure to delay the supply of the inputted power voltages. A power sequence controller 140 configured with a structure for delaying the supply of the power voltages will now e described in detail with reference to FIG. 3.

FIG. 3 is a schematic block diagram illustrating a power sequence controller capable of use in the multi-chip system embodiment of FIG. 1.

Referring to FIG. 3, the power sequence controller 140 may include logic circuits AND1, AND2, . . . , AND(N-1) (where N is an integer equal to or greater than 2) performing N-1 AND operations, and N-1 number of delay elements DE1, DE2, . . . , DE(N-1). Here, at least two of the respective delay elements DE1, DE2, . . . , DE(N-1) may have different delay times, and the other delay elements may have the same delay time. As another example, all of the delay elements DE1, DE2, and DE(N-1) may have the same delay time.

The power sequence controller 140 may be configured such that power voltages from an N-th power voltage VccN to a first power voltage Vcc1 are sequentially supplied. That is, the N-th power voltage VccN may be supplied first and the first power voltage Vcc1 may be supplied last, all under the control of the power sequence controller 140.

For example, the N-th power voltage VccN may be supplied directly to an N-th chip 12_N. An AND operation may be performed on the N-th power voltage VccN delayed by the (N-1)-th delay element DE(N-1) and an inputted (N-1)-th power voltage Vcc(N-1). The output voltage Vcc(N-1) of the AND operation may then be supplied to the (N-1)-th chip 12_(N-1). Accordingly, the supply of the (N-1)-th power voltage Vcc(N-1) to the (N-1)-th chip 12_(N-1) may be delayed by the delay time of the delay element DE(N-1) as compared to the supply of the N-th power voltage VccN to the N-th chip 12_N.

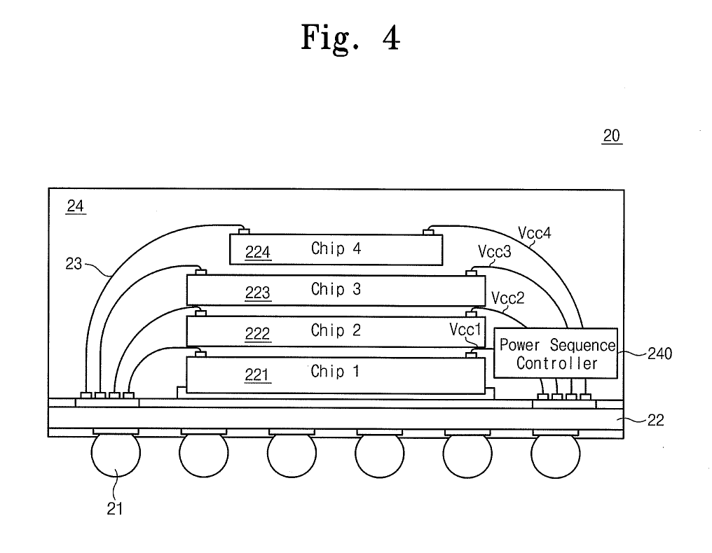

FIG. 4 is a schematic illustration of a multi-chip package configured for use in the multi-chip system of FIG. 1. Referring to FIG. 4, a multi-chip package 20 may include a first chip 221, a second chip 222, a third chip 223, a fourth chip 224, and a power sequence controller 240. The first to fourth chips 221 to 224 may be sequentially stacked on a ball land 22. The ball land 22 may be formed on a plurality of solder balls 21.

As shown in FIG. 4, gold wire 23 may be used to provide the internal wiring of the multi-chip package 20. The inside of the multi-chip package 20 may be filled with a molding material 24.

The first to fourth chips 221 to 224 may comprise one or more of DRAMs, SRAMs, NOR flash memories, NAND flash memories, controllers, and various application-specific integrated circuit (ASIC) chips. The power sequence controller 240 may input power voltages into the multi-chip system 20 and supply various power voltages to the first to fourth chips 221 to 224 according to a predetermined sequence.

For example, the power sequence controller 240 may first supply a fourth power voltage Vcc4 to the fourth chip 224, and then may sequentially supply a third power voltage Vcc3 to the third chip 223, a second power voltage Vcc2 to the second chip 222, and a first power voltage Vcc1 to the first chip 221.

The inventive concepts may, for instance, be applied to a moviNAND. The moviNAND may be an embedded storage medium with a NAND flash memory and a Multi Media Card (MMC) controller combined into one package.

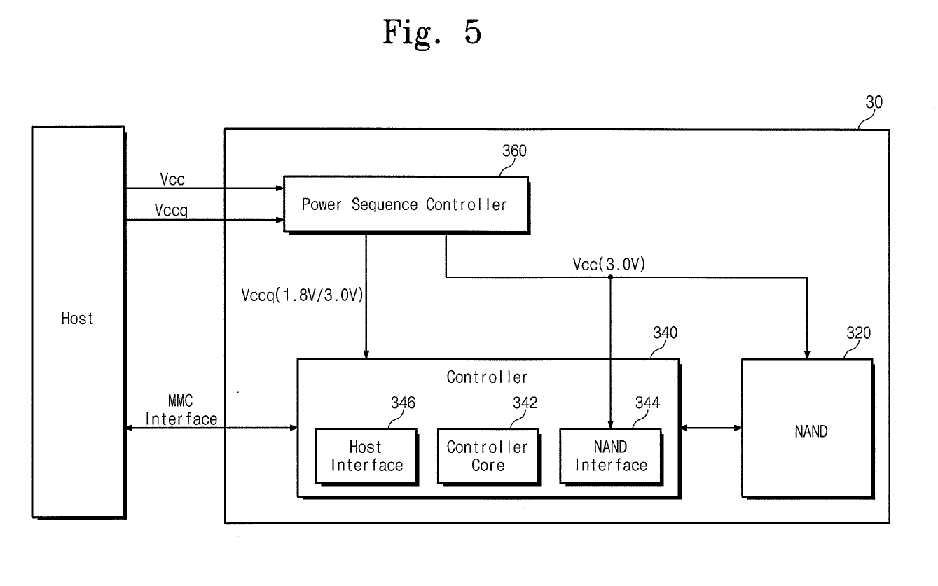

FIG. 5 is a schematic block diagram illustrating a moviNAND constructed according to an embodiment of the present inventive concepts. Referring to FIG. 5, a moviNAND 30 may include a NAND flash memory 320, a controller 340, and a power sequence controller 360.

The NAND flash memory 320 may be configured such that NAND flash memories of a single product are stacked in one package (e.g., a Fine-pitch Ball Grid Array (FBGA)). Here, the NAND flash memory 320 may include a multi-level cell or a signal level cell.

The controller 340 may include a controller core 342, a NAND interface 344, and a host interface 346. The controller core 342 may control all operations of the moviNAND 30. The NAND interface 344 may perform an interfacing between the NAND flash memory 320 and the controller 340. The host interface 346 may perform an MMC interfacing between the controller 340 and the outside (e.g., host).

The power sequence controller 360 may supply inputted power voltages Vcc and Vccq to the NAND flash memory 320, the NAND interface 344, or the controller 340, according to a predetermined sequence. Here, the power voltage Vcc (about 3V) may be supplied to the NAND flash memory 320 and the NAND interface 344, and the power voltage Vccq (about 1.8V/3V) may be supplied to the controller 340. The controller 340 may be supplied with a power voltage of about 1.8V or about 3V. When powered up, the power sequence controller 360 may supply the power voltage Vcc to the NAND flash memory 320 and the NAND interface 344, and then may supply the power voltage Vccq to the controller 340.

Although not shown, the NAND flash memory 320 may have a stacked structure of NAND flash memories in a single package. In this case, the power sequence controller 360 may also control the sequence of the power voltages to be supplied to the stacked NAND flash memories, respectively.

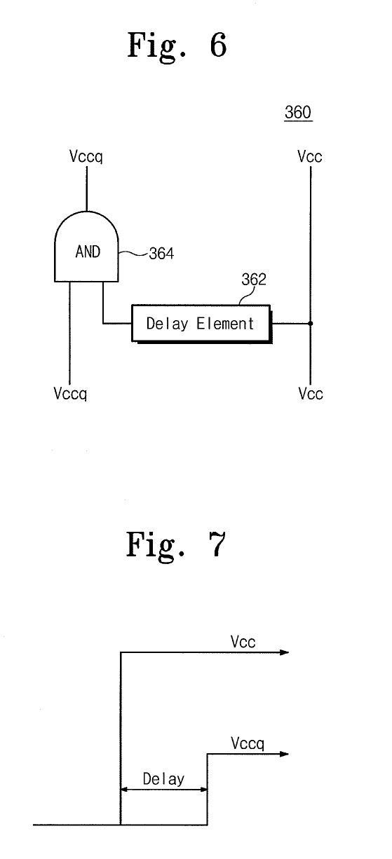

FIG. 6 is a schematic block diagram illustrating an exemplary power sequence controller for the moviNAND 30 of FIG. 5. Referring to FIG. 6, the power sequence controller 360 may include a delay element 362 and a logic circuit 364.

The delay element 362 may delay an inputted power voltage Vcc by a certain time. The logic circuit 364 may receive the delayed power voltage Vcc and the inputted power voltage Vccq, and then perform an AND logic operation. That is, if the delayed power voltage Vcc is a logic ‘high level’, and the inputted power voltage Vccq is a logic ‘high level’, then the power voltage Vccq may be outputted. In this case, the voltage Vccq outputted from the logic circuit 364 may be supplied to the controller 340.

FIG. 7 is a schematic diagram illustrating a power supply sequence for the power sequence controller of FIG. 6. Referring to FIG. 7, the power voltage Vcc may first be supplied to the NAND flash memory 320 and the NAND interface 344, and after the lapse of a certain time, the power voltage Vccq may be supplied to the controller 340. That is, after the NAND flash memory 320 and the NAND interface 344 are enabled, the controller 340 may be enabled.

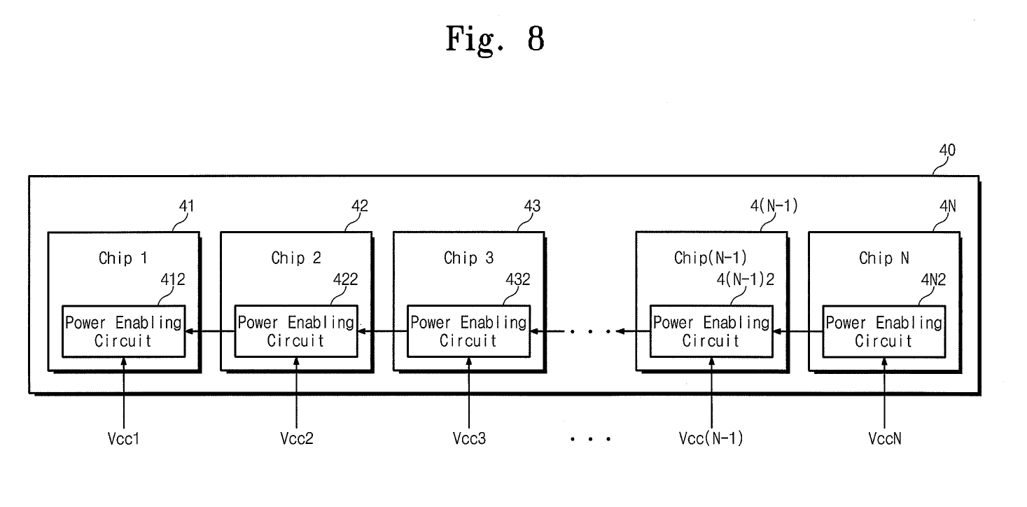

FIG. 8 is a schematic block diagram illustrating a multi-chip system according to another embodiment.

Referring to FIG. 8, a multi-chip system 40 may include a plurality of chips 41, 42, . . . , 4N, where N is an integer equal to or greater than 2. The plurality of chips 41, 42, . . . , 4N may include power enabling circuits 412, 422, and 4N2, respectively. The respective power enabling circuits 412, 422, . . . , 4(N-1)2 may determine whether to supply inputted power voltages Vcc1, Vcc2, Vcc(N-1) to the chips 41, 42, . . . , 4(N-1) according to the enabling state of the neighboring chips. Enabling of the chip means that the chip reaches a certain voltage level necessary for internal operation.

Operation of the power enabling circuits 412, 422, . . . , 4N2 will now be described in detail. First, N-th power enabling circuit 4N2 may supply an inputted power voltage VccN directly to the N-th chip 4N and may further generate an enabling signal when the N-th chip 4N is enabled. In this case, the generated enabling signal may be delivered to the (N-1)-th power enabling circuit 4(N-1)2.

The (N-1)-th power enabling circuit 4(N-1)2 may in turn supply an (N-1)-th power voltage Vcc(N-1) to the (N-1)-th chip 4(N-1) in response to the enabling signal delivered from the N-th power enabling circuit 4N2. Similarly, the (N-1)-th power enabling circuit 4(N-1)2 may be configured to generate an enabling signal when the (N-1)-th chip 4(N-1) is enabled. In this case, the generated enabling signal may be delivered to the N-2-th power enabling circuit 4(N-2)2.

According to the method described above, the first power enabling circuit 412 may supply the first power voltage Vcc1 to the first chip 41 in response to the enabling signal delivered from the second power enabling circuit 422. The enabling signal delivered from the second power enabling circuit 422 may be a signal generated from the second power enabling circuit 422 when the second chip 42 is enabled. Through this process, the first to N-th chips 41 to 4N may be supplied with the power voltages Vcc1, Vcc2, . . . , VccN, respectively.

On the other hand, the power enabling circuits 412, 422, . . . , 4N2 shown in FIG. 8 may be configured differently from each other. For example, the first power enabling circuit 412 need not be configured to generate an enabling signal, but can instead supply the first power voltage Vcc1 to the first chip 41 in response to the enabling signal delivered from the second power enabling circuit 422. The N-th power enabling circuit 4N2 may supply the inputted power voltage VccN directly to the N-th chip 4N, and may generate an enabling signal when the N-th chip 4N is enabled. The enabling signal is then delivered to the (N-1)-th power enabling circuit 4(N-1)2. The other power enabling circuits 422 to 4(N-1)2 may be supplied with power voltages in response to an enabling signal delivered from a neighboring power enabling circuit. They may in turn generate enabling signals when their respective chips are enabled and then deliver the enabling signals to different neighboring power enabling circuits.

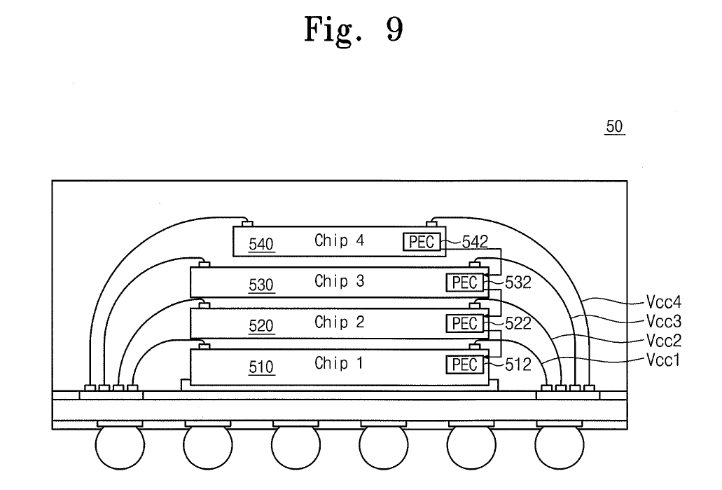

FIG. 9 is a schematic illustration of a multi-chip package configured to provide the multi-chip system of FIG. 8. Referring to FIG. 9, a multi-chip 50 package may include a first chip 510, a second chip 520, a third chip 530, and a fourth chip 540. The chips 510, 520, 530 and 540 may include power enabling circuits 512, 522, 532 and 542, respectively. Each of the power enabling circuits 512, 522, 532 and 542 may determine whether to supply power according to the enabling state of a respective neighboring chip.

For example, the fourth power enabling circuit 542 may supply a fourth external power voltage Vcc4 to the fourth chip 540, and may generate an enabling signal when the fourth chip 540 is enabled. The enabling signal from the fourth chip 540 may then be delivered to the third power enabling circuit 532. The third power enabling circuit 532 may supply a third external power voltage Vcc3 to the third chip 530 in response to the enabling signal delivered from the fourth power enabling circuit 542. The third power enabling circuit 532 may then generate an enabling signal when the third chip 530 is enabled and deliver that enabling signal to the second power enabling circuit 522. Likewise, the second power enabling circuit 522 may supply a second external power voltage Vcc2 to the second chip 520 in response to the enabling signal delivered from the third power enabling circuit 532, and may generate an enabling signal when the second chip 520 is enabled. That enabling signal can then be delivered to the first power enabling circuit 512. And finally, the first power enabling circuit 512 may supply a first external power voltage Vcc1 to the first chip 510 in response to the enabling signal delivered from the second power enabling circuit 522. Once the first chip 510 is enabled, the power supply of the multi-chip package 50 may be completed.

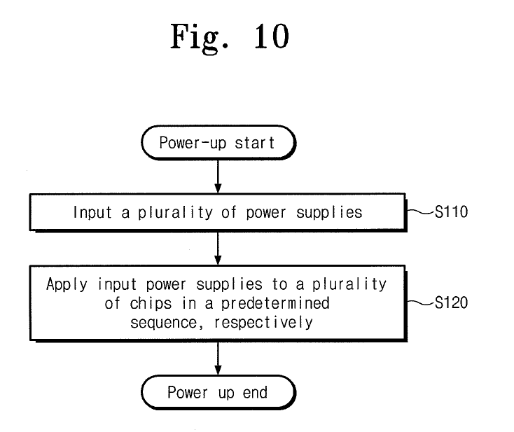

FIG. 10 is a flowchart illustrating a power-up method of a multi-chip system. Referring to FIG. 10, this power-up method for a multi-chip system may be performed as follows. In operation S110, a plurality of power voltages may be inputted into the multi-chip system. In operation S120, the inputted power voltages may be applied to respective chips of the multi-chip system according to a predetermined sequence.

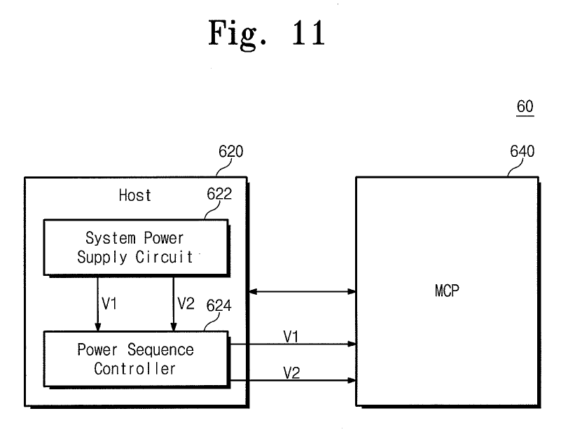

FIGS. 1 through 10 illustrate power sequence controllers arranged in multi-chip systems, but embodiments of the present inventive concepts are not limited thereto. For example, the power sequence controller may be located outside of the multi-chip system. A detailed description of one such embodiment will now be made with reference to FIG. 11.

FIG. 11 is a schematic block diagram illustrating a host system according to yet another embodiment of the inventive concepts disclosed herein. Referring to FIG. 11, a host system 60 may include a host 620 and a multi-chip package 640.

The host 620 may store data in the multi-chip package 640 or may read data from the multi-chip package. The host 620 may include such devices as computers, digital cameras, camcorders, mobile phones, and PDAs, for example. The host 620 may include a system power supply circuit 622 and a power sequence controller 624. The system power supply circuit 622 may generate power voltages V1 and V2 to be supplied to the multi-chip package 640. The power voltages V1 and V2 may have different power levels or the same power level.

The power sequence controller 624 may receive the power voltages V1 and V2 from the system power supply circuit 622, and may supply the power voltages V1 and V2 to the multi-chip package 640 according to a predetermined sequence. The power sequence controller 624 may be configured, for example, having the same structure as the power sequence controller 360 of FIG. 6.

The multi-chip package 640 may include a plurality of chips (not shown) driven by two power voltages V1 and V2. For example, the multi-chip package 640 may include at least one master chip (not shown) and at least one slave chip. For convenience of explanation, the power voltage V1 will be assumed to be a power voltage for the master, and the power voltage V2 will be assumed to be a power voltage for the slave. In this case, the multi-chip package 640 may first be supplied with the power voltage V2 for the slave from the power sequence controller 624, and may then be supplied with the power voltage V1 for the master. Alternatively, the multi-chip package 640 may include the elements of the moviNAND 30 of FIG. 5 other than the power sequence controller 360.

Another alternative embodiment of these inventive concepts may be applied to a Solid State Disk/Drive (SSD).

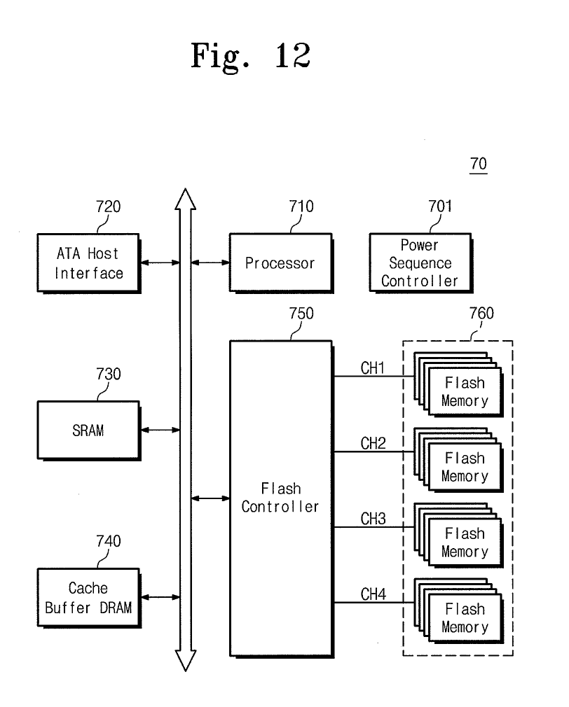

FIG. 12 is a schematic block diagram illustrating a Solid State Drive (SSD) according to a still further embodiment of these inventive concepts. Referring to FIG. 12, an SSD 70 may include a power sequence controller 701, a processor 710, an ATA host interface 720, a RAM 730, a cache buffer RAM 740, a flash controller 750, and a flash memory 760. When powered up, the power sequence controller 701 may supply power voltages to the processor 710, the ATA host interface 720, the RAM 730, the cache buffer RAM 740, the flash controller 750, and the flash memory 760 according to a predetermined sequence.

For example, when powered up, the power sequence controller 701 may first supply power voltages to the flash memory 760 and the flash controller 750 for controlling the flash memory 760. Thereafter, the power sequence controller 701 may supply power voltages to the processor 710, the ATA interface 720, the RAM 730, and the cache buffer RAM 740. In this case, the power to the processor 710, the ATA interface 720, the RAM 730, and the cache buffer RAM 740 may be simultaneously or sequentially supplied.

An ATA host interface 720 may exchange data with a host under the control of the processor 710. The ATA host interface 720 may fetch commands and addresses from the host and deliver the commands and addresses to the processor 710 through a CPU bus. Here, the ATA host interface 720 may be one of a SATA interface, a PATA interface, and an ESATA (External SATA) interface.

Data inputted from the host through the ATA host interface 720, or transmitted to the host, may be delivered through the cache buffer RAM 740 without passing the CPU bus under the control of the processor 710.

A RAM 730 may be used to temporarily store data necessary for the operation of the SSD 70. The RAM 730, which is a volatile memory, may, for instance, include DRAMs or SRAMs.

The cache buffer RAM 740 may temporarily store data transferred between the host and the flash memories 760. Also, the cache buffer RAM 740 may also be used to store programs to be executed by the processor 710. The cache buffer RAM 740 may be considered to be a kind of buffer memory, and may be configured using an SRAM.

The flash controller 750 may exchange data with the flash memories that are used as storage devices. The flash controller 750 may be configured to support NAND flash memories, One-NAND flash memories, multi level flash memories, and single level flash memories.

Alternatively, the processor 710 and the flash controller 750 may be configured using a single ARM processor.

A multi-chip system according to the inventive concepts can, for example, be used as a mobile storage device. Accordingly, the multi-chip system may, for instance, be used as a storage device in MP3 players, digital cameras, PDAs, e-books, digital TVs, and computers.

A multi-chip system and/or a storage device according to an embodiment of the inventive concepts may be mounted in various forms of packages.

For example, the multi-chip system and/or the storage device may be mounted in packages such as Package on Package (PoP), Ball Grid Arrays (BGAs), Chip Scale Packages (CSPs), Plastic Leaded Chip Carrier (PLCC), Plastic Dual In-line Package (PDIP), Die in Waffle Pack, Die in Wafer Form, Chip On Board (COB), Ceramic Dual In-line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), Thin Quad Flat Pack (TQFP), System In Package (SIP), Multi Chip Package (MCP), Wafer-level Fabricated Package (WFP), and Wafer-level Processed Stack Package (WSP).

Reference throughout this specification to “one embodiment” “some embodiments” or “an embodiment” means that a particular feature, structure, or characteristic described in connection with the embodiment is included in at least one embodiment of the present invention. Thus, the appearances of the phrases “in one embodiment,” “some embodiments,” or “in an embodiment” in various places throughout this specification are not necessarily all referring to the same embodiment. Furthermore, the particular features, structures, or characteristics may be combined in any suitable manner in one or more embodiments.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Various operations will be described as multiple discrete steps performed in a manner that is most helpful in understanding the invention. However, the order in which the steps are described does not imply that the operations are order-dependent or that the order that steps are performed must be the order in which the steps are presented.

The above-disclosed subject matter is to be considered illustrative and not restrictive, and the appended claims are intended to cover all such modifications, enhancements, and other embodiments, which fall within the true spirit and scope of the inventive concepts. Thus, to the maximum extent allowed by law, the scope of the inventive concepts is to be determined by the broadest permissible interpretation of the following claims and their equivalents, and shall not be restricted or limited by the foregoing detailed description.

What is claimed is:

1. A multi-chip system comprising:
a plurality of chips; and
a power sequence controller configured to supply a plurality of external power voltages to the plurality of chips according to a predetermined sequence.

2. The multi-chip system of claim 1, wherein the plurality of chips have a stacked structure.

3. The multi-chip system of claim 1, wherein the plurality of chips are memory chips of the same type.

4. The multi-chip system of claim 1, wherein the power sequence controller delays a supply of at least one of the external power voltages according to the predetermined sequence.

5. The multi-chip system of claim 1, wherein at least two of the plurality of external power voltages have different levels.

6. A multi-chip system comprising:
a first chip configured to generate an enabling signal when a first power voltage is supplied to the first chip and reaches a certain level; and
a second chip configured to be supplied with a second power voltage in response to the enabling signal from the first chip.

7. The multi-chip system of claim 6, wherein the first chip is a slave, and the second chip is a master.

8. A multi-chip system comprising:
at least one first chip configured to be supplied with a first power voltage;
at least one second chip configured to be supplied with a second power voltage; and
a power sequence controller configured to receive the first and second power voltages and further configured to supply the second power voltage to the at least one second chip after supplying the first power voltage to the at least one first chip.

9. The multi-chip system of claim 1, wherein the plurality of chips comprises a first chip and a second chip and wherein the plurality of external voltages comprises a first voltage and a second voltage.

10. The multi-chip system of claim 9, wherein according to the predetermined sequence, the power sequence controller is configured to supply the second voltage to the second chip before the first voltage is supplied to the first chip.

11. The multi-chip system of claim 10, wherein the first chip is a master and the second chip is a slave.

12. The multi-chip system of claim 11, wherein the first chip performs an identification operation to recognize the second chip after the first and second chips have both been enabled.

13. The multi-chip system of claim 1, wherein the power sequence controller comprises a plurality of logic circuits and delay elements configured to control the supply of the plurality of external power voltages according to the predetermined sequence.

14. The multi-chip system of claim 13, wherein the plurality of logic circuits comprises a plurality of AND gates.

15. The multi-chip system of claim 1 wherein the plurality of chips includes one or more of a memory chip, a controller, or an ASIC chip.

16. The multi-chip system of claim 1, wherein the plurality of chips provides a moviNAND comprising a NAND flash memory and a memory controller.

17. The multi-chip system of claim 6, further comprising a third chip supplied with a third power voltage in response to an enabling signal from the second chip.

18. The multi-chip system of claim 17, wherein each of the first and second chips comprises a power enabling circuit.

19. The multi-chip system of claim 8, wherein the power sequence controller comprises a plurality of logic circuits and delay elements configured to supply the second power voltage to the at least one second chip after supplying the first power voltage to the at least one first chip.

20. The multi-chip system of claim 8, further comprising a third chip configured to receive a third power voltage, and wherein the multi-chip system is configured to receive the third power voltage and to supply the third power voltage to the third chip after supplying the second power voltage to the second chip.
